(19) United States
(12) Patent Application Publication
(10) Pub. No.: US 2006/0063383 A1
(43) Pub. Date: Mar. 23, 2006

(54) CMP process endpoint detection method by monitoring and analyzing vibration data

(76) Inventor: Philip Hardy Pattengale JR., Loomis, CA (US)

Correspondence Address: CAMPBELL STEPHENSON ASCOLESE, LLP, 4807 SPICEWOOD SPRINGS RD., BLDG. 4, SUITE 201, AUSTIN, TX, 78759, US

(21) Appl. No.: 10/945,375

(22) Filed: Sep. 20, 2004

(51) Int. Cl. C03C 15/00; H01L 21/306; H01L 21/302

(52) U.S. Cl. 438/689; 216/89; 156/345.12; 156/345.13; 216/84

(57) ABSTRACT

An apparatus and method for monitoring vibration of a chemical-mechanical planarization (CMP) tool to detect CMP process endpoint. In one embodiment, the CMP tool includes a wafer carrier configured to directly or indirectly receive a semiconductor wafer. The carrier rotates the semiconductor wafer with respect to a polishing pad. It is noted that the polishing pad can also be rotated. An accelerometer is attached to the CMP tool and is configured to generate an electrical signal, wherein the electrical signal is being generated as a function of vibration within the CMP tool. A spectrum analyzer is coupled to the accelerometer and is configured to receive the electrical signal. The spectral analyzer generates a frequency spectrum as a function of the electrical signal. A computer system may be used to monitor one or more frequency components of the frequency spectrum. The computer system can be programmed to detect a predetermined change in one or more frequency components of the frequency spectrum that is indicative of CMP process endpoint. In one embodiment, the spectrum analyzer and computer system may be the same machine.

### BACKGROUND OF THE INVENTION

The manufacturer of semiconductor devices generally involves the formation of various layers on a semiconductor wafer, selective removal or patterning of portions of those layers, and formation of yet additional layers. The layers can include, by way of example, insulation layers, gate oxide layers, conductive layers, etc. It is generally desirable in semiconductor manufacturing that the surface of layers be planer, i.e., flat, for the deposition of subsequent layers.

Chemical-mechanical planarization (CMP) is a well known process used to planarize layers in semiconductor wafers. Traditionally, the process includes mounting a wafer upside down on a wafer carrier in a CMP tool. Newer CMP tools may be different. A force pushes the carrier and the wafer downward toward a polishing surface. Often, the polishing surface is rotated as well. In other words, the carrier and the wafer together are often rotated relative to the polishing pad. The carrier also can oscillate across the polishing pad on the polishing table. A polishing composition also known as polishing slurry, is introduced between the rotating wafer and polishing pad during the planarization process. The slurry typically contains a chemical that interacts with or chemically reacts (note: the chemical reaction is oxidation) with the uppermost wafer layer. Additionally, the slurry contains an abrasive material that physically removes portions of the layer as the wafer is rotated against the polishing pad. The CMP process results in a planar surface on a semiconductor wafer with little or no detectable scratches or excess material present on the wafer surface.

Precise control of wafer planarization is required during the CMP process, and it is necessary to periodically, if not continually, monitor the wafer in order to ensure sufficient but not excessive polishing of the wafer. The point at which excess material on a wafer surface is removed, but desired material remains, is called the endpoint of the CMP process. Over polishing (i.e., removing too much) of a wafer layer can damage the wafer surface, rendering the wafer unusable. Underpolishing, (i.e., removing too little) of the layer may require that the CMP process be repeated, which is inefficient and costly. Moreover, underpolishing may go unnoticed, which can cause subsequent processing difficulties and eventually render the wafer unusable. The time interval between the states of underpolishing and overpolishing can be small, e.g., on the order of a few seconds. Thus, accurate in-situ CMP process endpoint detection is highly desirable.

The time needed to achieve CMP process endpoint for a wafer can be estimated using the time it took to achieve CMP process endpoint for a previous wafer of the same type. However, estimating the endpoint using this method may not be accurate because polishing conditions can change. For example, the time needed to achieve CMP process endpoint may change as the polishing pad and/or slurry age in the CMP tool. On the other hand, removing the wafer from the carrier and measuring the thickness of the layer being polished in an effort to determine the polishing endpoint is time consuming and can damage the wafer, thus reducing the throughput of the CMP process.

Some current techniques used for in-situ CMP process endpoint detection include optical reflection, thermal detection, and friction-based techniques. Optical reflection techniques are not employed often due to problems that lead to inaccurate results. Thermal imaging involves the remote sensing of temperature across the polishing pad using techniques such as pyrometry and fluoroptic thermometry. Thermal techniques suffer from thermal noise caused by variations in the polishing slurry, or changes in the polishing pad. Thermal techniques are also adversely impacted by complexity in the thermal variations as the CMP tool warms and cools over the operation cycle and carrier oscillations. As a result, thermal techniques can be inaccurate and are rarely used.

Friction-based techniques detect the endpoint by monitoring change in the friction coefficient between the wafer surface and the polishing pad. The coefficient of friction is different, for example, for a conductive metal sliding on the polishing pad verses an insulating oxide sliding on the polishing pad. The level of friction can be measured by several methods, including monitoring the frictional force, monitoring the power consumed by the CMP tool's carrier motor, or by measuring the change in torque of the shaft that rotates the carrier. Friction-based techniques are satisfactory when there is a significant change in friction as the underlying layer is exposed. However, friction-based techniques also have drawbacks. For many applications, the change in friction associated with the interference between layers is too small to result in a change sufficient to be a reliable indicator of the CMP process endpoint. This is particularly a problem when there is little difference between the materials of two layers. For example, a small data ratio (that is, a relatively small area of underlying pattern layer compared with the area of the entire layer) causes only a small change in friction as the endpoint is reached, thereby limiting the useful signal used to determine CMP process endpoint. The problem can be further compounded by large noise components. Indeed, even with filtering, the frequency signals may have complex shapes that mask the relatively subtle change caused when endpoint is reached. As such, there remains a need for an improved method of monitoring for CMP process endpoint.

### SUMMARY OF THE INVENTION

An apparatus and method is disclosed for monitoring vibration of a chemical-mechanical planarization (CMP) tool to detect CMP process endpoint. In one embodiment, the CMP tool includes a wafer carrier configured to directly or indirectly receive a semiconductor wafer. The carrier rotates the wafer with respect to a polishing pad. The polishing pad may also be rotated. An accelerometer is attached to the CMP tool and is configured to generate an electrical signal, wherein the electrical signal is proportional to acceleration caused by CMP tool vibration. The vibration results from polishing the semiconductor wafer. A spectral analyzer is coupled to the accelerometer and is configured to receive the electrical signal. The spectral analyzer generates a frequency spectrum as a function of the electrical signal. A computer system may be used to monitor one or more frequency components of the power spectrum. The computer system can be programmed to detect a predetermined change in one or more frequency components of the frequency spectrum that is indicative of CMP process endpoint. In one embodiment, the functions of the FFT analyzer may be performed by the computer system. In other words, the FFT analyzer and computer system may take form in one device.

### BRIEF DESCRIPTION OF THE DRAWINGS

The present invention may be better understood, and its numerous objects, features, and advantages made apparent to those skilled in the art by referencing the accompanying drawings.

FIG. 1 shows a block diagram of relevant components of a CMP system employing one embodiment of the present invention;

FIGS. 2A-2C show cross sections of a semiconductor wafer during various stages of the CMP process;

FIGS. 3A-3C illustrate graphical representations of the frequency spectrum generated by the FFT spectrum analyzer of FIG. 1 during the various stages of the CMP process.

The use of the same reference symbols in different drawings indicates similar or identical items.

### DETAILED DESCRIPTION

The present invention is directed to a method and apparatus for in-situ monitoring of CMP process endpoint. The method involves receiving a real time data signal from a sensor mounted within a CMP system and transforming the real time data signal into a frequency spectrum (e.g., a frequency domain representation of the signal) of frequency components, whose sum is substantially equal to that of the real time data signal. The sensor may take form in an accelerometer and the real time data signal may take form in the signal generated by the accelerometer. Through frequency decomposition of the signal generated by the sensor (e.g., the accelerometer), in-situ monitoring of the CMP process can be achieved. Individual frequency components of the frequency spectrum correspond to different aspects of the CMP process executing within the CMP tool. By monitoring one or more frequency components of the frequency spectrum for changes in amplitude and/or frequency during the CMP process, important events in the CMP process such as CMP process endpoint can be detected. When a particular change in amplitude and/or frequency in at least one selected frequency component is detected, the CMP process can be altered in response as appropriate to ensure that the wafer being polished is properly processed.

Any suitable algorithm can be used to convert the real time data signal from the sensor mounted within the CMP system into constituent frequency components. The individual frequency components can be identified and monitored in real time. Preferably, the data signal is transformed into various frequency components by one or more processors executing instructions in accordance with a mathematical algorithm. In one embodiment of the invention, the algorithm is a Fast Fourier Transform (FFT). The use of an FFT allows for real time processing of the frequency components of the power spectrum.

At least one frequency component is identified as corresponding to an aspect of the CMP process. For example, frequency components can be identified based on amplitude and/or frequency as pertaining to carrier rotation, table rotation, automation (e.g., the automatic loading or unloading of semiconductor wafers), or tribology. By separating the data signal into different frequency components, a frequency component of interest can be observed and monitored without interference from other frequency components, i.e., background noise. At least one of the individual frequency components is monitored in real time, i.e., during the CMP process. It is noted that the present invention can also be applied to monitoring two or more frequency components in tandem. The amplitude and/or frequency from the two or more individual frequency components of the frequency spectrum can be combined in any suitable way to more accurately observe a desired change in the CMP process. Moreover, one or more individual frequency components obtained from one data signal can be combined with one or more individual frequency components obtained from another real time data signal in any way, so as to more accurately observe a desired change.

The detection in the change of the amplitude and/or frequency of one or more frequency components of the frequency spectrum can be accomplished by any suitable technique. For example, the detection of a change can be accomplished using a properly programmed computer system continuously monitoring the frequency spectrum provided by the FFT analyzer. Alternatively, a user visually inspecting a graphical representation of the frequency spectrum may be able to detect a change in amplitude and/or frequency of one or more frequency components. The CMP process can be altered in response to the detected change. For example, the computer system mentioned above can be coupled to monitor the frequency spectrum such that when the computer system detects a particular change in the amplitude and/or frequency of at least one frequency component, the computer system alters the CMP process by issuing an instruction. Termination of the CMP process is an exemplary instruction that may be issued by the computer system.

The method can be used to monitor a variety of CMP process aspects. For example, a detected change in frequency component amplitude and/or frequency can be in response to or be indicative of an aspect of the CMP process, such as CMP process endpoint, polishing pad wear, undesirable vibration in the polishing process, wafer defect, and/or a change in the application of polishing slurry to the polishing pad. The present invention provides in-situ monitoring and diagnosis of any or all aspects and events relevant to the CMP process. In a preferred embodiment, the method is used for detecting CMP process endpoint. The present invention can be used to monitor one or more frequency components to identify a change in vibration during the CMP process that is indicative of CMP process endpoint.

The present invention can be employed within any suitable CMP system. In one embodiment, the CMP system includes at least one sensor coupled to a CMP tool, wherein the sensor is configured to generate a real time data signal indicative of vibration in the CMP tool. The data signal output from the sensor is transmitted to an FFT analyzer. The FFT analyzer in turn generates a frequency spectrum as a function of the data signal output of the sensor. In one embodiment, the frequency spectrum generated by the FFT analyzer is provided to a computer system which is programmed to monitor one or more frequency components of the frequency spectrum in order to detect changes indicative of a CMP process event such as CMP process endpoint. In one embodiment, the FFT analyzer and process to monitor the frequency spectrum may be implemented on a single machine. For example, the FFT analyzer may take form in a program executing on the computer system used for monitoring the frequency spectrum. For purposes of explanation only, the present invention will be described with reference to separate machines for producing the frequency spectrum and monitoring the frequency spectrum.

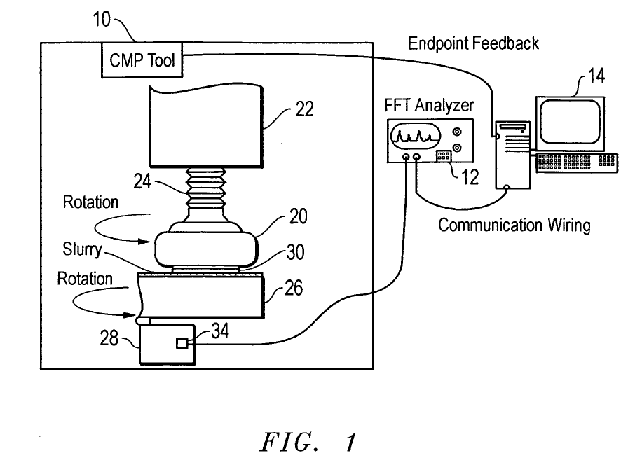

FIG. 1 illustrates in block diagram form relevant components of a CMP system employing one embodiment of the present invention. More particularly, the CMP system shown in FIG. 1 includes a CMP tool 10 coupled to a FFT spectrum analyzer 12 via a sensor (e.g., an accelerometer) and a computer system 14. The CMP tool can be any suitable CMP tool, including conventional CMP tools known in the art. Computer system 14 can be any computer and can include a personal computer (desktop or laptop), a work station, a network server, or a main frame computer. The computer can operate under any suitable operating system, such as Windows, Unix, or MacOS. Computer system 14 is in data communication with CMP tool 10 via bus system that operates over a traditional network protocol or simply dry contacts (e.g., relays). Exemplary network protocols include Ethernet, Rambus, and Fire Wire. FFT spectrum analyzer 12 may take from in the HP3571A Spectrum Analyzer provided by Agilent.

The CMP tool 10 shown in FIG. 1 includes a wafer carrier 20 on which a wafer 30 is mounted directly or indirectly. A foam pad (not shown) may be positioned between wafer 30 and carrier 20. Carrier 20 is coupled to a bridge frame 22 via a spindle 24. Bridge frame 22 operates to mount, oscillate, and rotate the spindle which holds the wafer carrier. CMP tool 10 further includes a polishing table 26 that supports a polishing pad (not shown). The polishing table is coupled to a machine frame 28. Machine frame 28 fixes all sub-components (e.g., the polishing table) of the CMP tool in relation such that they can work together to polish a semiconductor wafer. Slurry is introduced onto the polishing pad for chemical-mechanical polishing of wafers 30. Wafer carrier 20 rotates wafer 30 relative to the polish table 26. It is noted that polish table 26 can rotate in a direction which is the same as or opposite to the rotation of wafer carrier 20. The polishing pad with slurry performs the chemical-mechanical planarization of wafer 30 as it rotates. The polishing pad, the foam pad, and the slurry are consumables in that they need to be replaced at time intervals.

One or more sensors may also be attached to one or more components of CMP tool 10. For purposes of explanation, sensor 34 is coupled to machine frame 28. It is noted, however, that additional sensors may be attached to, for example, spindle 24 or bridge 22. In general, it is best to attach sensor 34 to the CMP tool 10 in close proximity to the polishing surface of the semiconductor wafer. In one embodiment, sensor 34 can be attached to the polishing table gearbox. In another embodiment, sensor 34 can be attached to the spindle. It is further noted that two or more sensors may be grouped together and attached to a component of the CMP tool 10. Each of the two or more sensors grouped together can be configured to measure acceleration caused by vibration in different axial directions.

Sensor 34 may take one of many different forms. For purposes of explanation, it will be presumed that sensor 34 takes form in an accelerometer. Accelerometers measure vibration as acceleration. Sensor 34 generates a signal as a function of mechanical vibration of the CMP tool 10. Thus, sensor 34 generates a data signal proportional to the mechanical vibration of the CMP tool 10. The accelerometer may include a strain gage or a piezoelectric device for transforming mechanical vibration energy into corresponding electrical signals. Although the accelerometer may use strain gauge and piezoelectric technology to measure the acceleration, the accelerometer may further include electronics to create the desired output signal. The piezoelectric accelerometer is based on a property exhibited by certain crystals where a voltage is generated across the crystal when stressed. For accelerometers, a piezoelectric crystal is spring-loaded with a test mass in contact with the crystal. When exposed to an acceleration, the test mass stresses the crystal by a force (F=ma), resulting in a voltage generated across the crystal. A measure of this voltage is then a measure of the acceleration. The crystal per se is a very high-impedance source, and thus requires a high-input impedance, low-noise detector. Output levels are typically in the millivolt range. The natural frequency of these devices may exceed 5 kHz, so that they can be used for vibration and shock measurements.

The data signal output of sensor 34 is transmitted to FFT spectrum analyzer 12. It is noted that FFT spectrum analyzer 12 can receive and process data signals from several sensors (e.g., accelerometers) attached to respective components within CMP tool 10. FFT spectrum analyzer 12 processes data signals from one or more sensors to generate a frequency spectrum. The frequency spectrum in turn is provided to computer system 14. Computer system 14 monitors the frequency spectrum provided by FFT spectrum analyzer 12 over time to detect changes in the amplitude and/or frequency of one or more frequency components. A change in the amplitude and/or frequency of at least one frequency component of the frequency spectrum may be indicative of an aspect (e.g., an event) in the CMP process. Computer system 14, in response to detecting a particular change in amplitude and/or frequency of at least one frequency component, responds by issuing an instruction to CMP tool 10 to alter the CMP process. A change in the CMP process can be affected in any suitable manner. For example, computer system 14 may issue an instruction to terminate the CMP process performed on wafer 30 in response to detecting a particular change in amplitude and/or frequency of at least one frequency component.

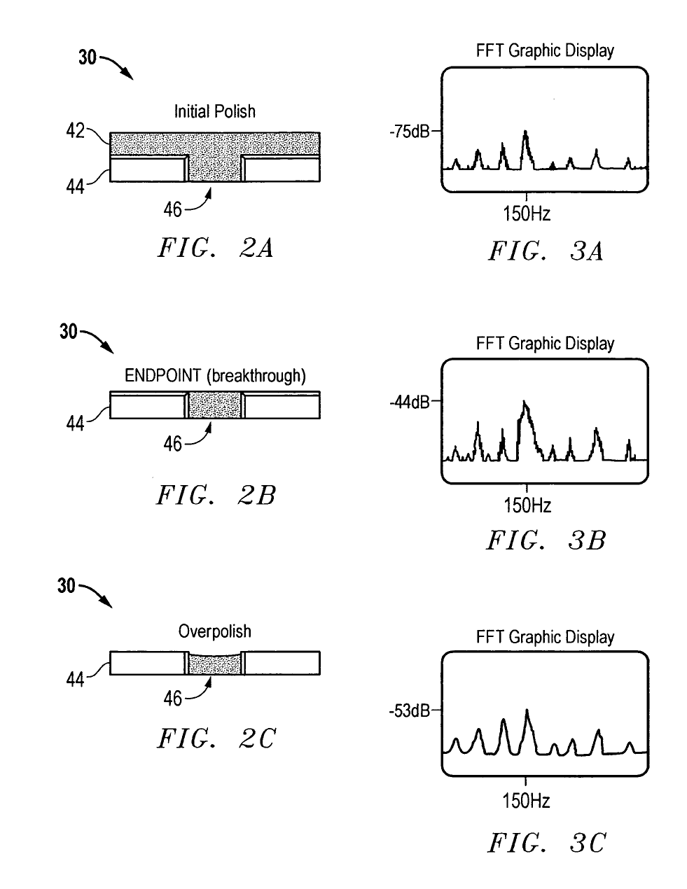

Operational aspects of system 10 are best described with reference to FIGS. 2A-2C and 3A-3C. FIGS. 2A-2C illustrate a cross-sectional view of exemplary semiconductor wafer 30 during various stares of CMP, while FIGS. 3A-3C respectively illustrate graphical representations of the frequency spectrum generated by FFT spectrum analyzer 12 at the various stages of CMP. As shown in FIG. 2A, wafer 30 consists of a metal layer 42 deposited on an insulating layer 44. The metal may take form in tungsten or any other suitable metal which can conduct electrical signals. A portion of metal layer 42 extends through a via 46 formed in insulating layer 44. Ultimately, this portion of metal layer 42 will form a contact that will be used to form an electrical connection between different sub-layers in the semiconductor wafer. FIG. 2A represents the cross section of wafer 30 as wafer 30 is polished by CMP tool 10 process prior to CMP process endpoint. FIG. 3A graphically represents the vibration of CMP tool 10 in the frequency domain as wafer 30 is polished by CMP tool 10 process prior to CMP process endpoint.

FIG. 2B illustrates the wafer 30 around the time CMP process endpoint is reached. As can be seen in FIG. 2B, the entire metal layer 42 has been substantially removed by the CMP process. The portion of metal layer 42 contained within via 46 remains intact at CMP process endpoint. FIG. 3B illustrates the frequency spectrum produced by FFT spectrum analyzer 12 around the time CMP process endpoint is achieved.

FIG. 2C illustrates wafer 30 after CMP process endpoint is achieved and over polishing has begun. FIG. 2C shows that overpolishing results in the removal of some of the insulating layer 44. FIG. 3C is an example of the frequency spectrum provided by FFT spectrum analyzer 12 after CMP process endpoint is achieved and while wafer 30 continues to be polished.

The frequency spectrum differs within FIGS. 3A-3C. More particularly, FIGS. 3A and 3B when compared, illustrate that one or more frequency components change in amplitude and/or frequency as the CMP process goes through endpoint. For example, FIG. 3A shows an amplitude of −75 dB at 150 Hz while the metal layer 42 is being polished. When the endpoint is achieved, the amplitude at 150 Hz increases to −44 dB as shown in FIG. 3B. The change in frequency amplitude is not sudden; rather, there is a SHORT period of time when the amplitudes increases from −75 dB to −44 dB. A comparison of FIGS. 3B and 3C shows a further change in the frequency components of the frequency spectrum when the CMP process enters the overpolishing state. After endpoint has been achieved, amplitudes in one or more frequency components decrease until a steady state is reached. For example, FIG. 3C shows the steady state after the endpoint is achieved and when a substantial surface area of insulator 44 is being polished. In FIG. 3C, the amplitude at 150 Hz for example decreases to −53 dB and stays at that level. The change in amplitude is not sudden; rather, there is a period of time when the amplitudes decreases from −44 dB to −53 dB.

Computer system 14 can be programmed to recognize a predetermined increase (or decrease) in amplitudes of one or more frequency components in the frequency spectrum as indicative of a CMP process event. For example, computer system 14 can be programmed to recognize an increase of 25 dB at 150 Hz as indicative of wafer 30 passing through the CMP process endpoint. In another example, computer system 14 can be programmed to recognize a decrease in amplitude at 150 Hz (or other frequencies). For purposes of explanation, it will be presumed that computer system 14 is programmed to recognize an increase in amplitude at 150 Hz that is indicative of CMP process endpoint. When the 25 dB increase is recognized, the computer system can instruct the CMP tool 10 to terminate polishing or continue to polish wafer 30 for a certain amount of time e.g., ten seconds.

There are many sources of CMP tool vibration with tribology being an example of just one. Shearing or breaking of bonds, temperature differences, chemical reaction differences, etc., may also contribute to the change in vibration as the CMP process proceeds through endpoint. Vibration is the sum total of energy generated and dissipated in the CMP tool during the CMP process. The change vibration represents a change in the sum total of energy generated and dissipated. Sources of the energy generated or dissipated include the polish tribology. More energy is required to polish one material (e.g., SiO₂) than another (e.g., metal). As the material being polished is changed, the energy required to polish such a material is changed.

Although the present invention has been described in connection with several embodiments, the invention is not intended to be limited to the specific forms set forth herein. On the contrary, it is intended to cover such alternatives, modifications, and equivalents as can be reasonably included within the scope of the invention as defined by the appended claims.

I claim:

1. An apparatus comprising:
a chemical-mechanical planarization (CMP) tool for rotating a semiconductor wafer, wherein the CMP tool comprises a wafer carrier configured to directly or indirectly receive the semiconductor wafer;
an accelerometer attached to the CMP tool and configured to generate an electrical signal, wherein the electrical signal is generated as a function of vibration of the CMP tool;
a spectral analyzer coupled to the accelerometer and configured to receive the electrical signal.

2. The apparatus of claim 1 wherein the spectral analyzer is configured to generate a frequency spectrum, wherein the frequency spectrum comprises different frequency components, wherein a sum of the different frequency components is substantially equal to the electrical signal.

3. The apparatus of claim 2 wherein spectral analyzer is configured to generate the frequency spectrum using a fast Fourier transform (FFT) algorithm.

4. The apparatus of claim 2 wherein the CMP tool comprises a polishing pad that engages the semiconductor wafer as it is rotated.

5. The apparatus of claim 4 further comprising a computer system in data communication with the spectral analyzer, wherein the computer system is configured to:
receive the frequency spectrum generated by the spectral analyzer;
detect a change in one or more frequency components which indicate a polishing endpoint for the semiconductor wafer.

6. An apparatus comprising:
a CMP tool for rotating a semiconductor wafer, wherein the CMP tool comprises a wafer carrier configured to directly or indirectly receive the semiconductor wafer;
an piezoelectric device attached to the CMP tool and configured to generate an electrical signal, wherein the electrical signal is generated by the piezoelectric device as a function of vibration of the CMP tool;
a spectral analyzer coupled to the piezoelectric device and configured to receive the electrical signal.

7. An apparatus comprising:
means for rotating a semiconductor wafer, wherein the means for rotating comprises a wafer carrier configured to directly or indirectly receive the semiconductor wafer;
a means for generating electrical signal that is related to vibration of the means for rotating;
a means for generating a frequency spectrum as a function of the electrical signal.

8. The apparatus of claim 7 wherein the means for generating the frequency spectrum comprises a processor for processing the electrical signal according to a fast Fourier transform (FFT) algorithm.

9. The apparatus of claim 7 wherein the means for rotating comprises a polishing pad for contacting the semiconductor wafer as it is rotated.

10. The apparatus of claim 9 further comprising a computer system in data communication with the means for generating the power spectrum, wherein the computer system is configured to:
receive the frequency spectrum generated by the means for generating the frequency spectrum;
detect a polishing endpoint OF the semiconductor wafer using one or more frequency components of the frequency spectrum.

11. A method comprising:
a chemical-mechanical planarization (CMP) tool rotating a semiconductor wafer, wherein the CMP tool vibrates as the semiconductor wafer is rotated and polished;
an accelerometer generating an electrical signal as a function of the CMP tool vibration;
generating a frequency domain representation of the electrical signal.

12. The method of claim 11 further comprising:
a computer system monitoring at least one frequency component of the frequency domain representation of the electrical signal;
wherein the computer system generates an instruction when the computer system detects a change in amplitude and/or frequency of the at least one frequency component of the frequency domain representation.

13. The method of claim 11 wherein the frequency domain representation of the electrical signal is generated using a fast Fourier transform (FFT) algorithm.

14. The method of claim 11 further comprising an act of removing a portion of a first layer deposited on a second layer of the semiconductor wafer as the semiconductor wafer is rotated and polished.

15. A method comprising:
a chemical-mechanical planarization (CMP) tool rotating a semiconductor wafer, wherein the CMP tool vibrates as the semiconductor wafer is rotated and polished;
a piezoelectric device generating an electrical signal as a function of the CMP tool vibration;
generating a frequency domain representation of the electrical signal.

16. The apparatus of claim 1 wherein the accelerometer is attached to the CMP tool in close proximity to a polishing surface of the semiconductor wafer.

17. The apparatus of claim 4 wherein the polishing pad is rotated.

18. The apparatus of claim 1 further comprising a computer system wherein the spectral analyzer takes form in a set of instructions executing on one or more processors of the computer system, wherein the computer system is configured to:
receive the frequency spectrum generated by the spectral analyzer;
detect a change in one or more frequency components which indicate a polishing endpoint for the semiconductor wafer.
